(19) United States
(12) Patent Application Publication
(10) Pub. No.: US 2024/0429107 A1
(43) Pub. Date: Dec. 26, 2024

(54) METHOD FOR REDUCING MEASUREMENT ERRORS IN CRITICAL PATTERN DIMENSIONS OF POLYCRYSTAL LAYERS

(71) Applicant: Shanghai Huali Integrated Circuit Corporation, Shanghai (CN)

(72) Inventors: Guanbo Yin, Shanghai (CN); Zhonghua Zhu, Shanghai (CN); Fang Wei, Shanghai (CN)

(73) Assignee: Shanghai Huali Integrated Circuit Corporation, Shanghai (CN)

(21) Appl. No.: 18/644,604

(22) Filed: Apr. 24, 2024

(30) Foreign Application Priority Data
Jun. 21, 2023 (CN) 202310749893.9

(51) Int. Cl. H01L 21/66; H01J 37/28

(52) U.S. Cl. CPC H01L 22/12; H01J 37/28; H01J 2237/2817

(57) ABSTRACT

A method is disclosed for reducing measurement errors on wafer circuit pattern critical dimensions of polycrystal layers: providing wafer circuit patterns to be measured; defining rules to classify the wafer circuit patterns into a first type and a second type, the first type is easily measurable and the second type is not easily measurable with an electron beam linewidth defect scanning machine; for the first type, performing automatic measurement with the machine; for the second type, aligning the user designed wafer circuit patterns manually with the second type of wafer circuit patterns, and performing by the machine to obtain measurement results twice.

### CROSS-REFERENCE TO RELATED APPLICATIONS

This application claims priority to Chinese patent application No. 202310749893.9, filed on Jun. 21, 2023, the disclosure of which is incorporated herein by reference in its entirety.

### TECHNICAL FIELD

This application relates to the field of semiconductor technology, and in particular to a method for reducing measurement errors of critical pattern dimensions of polycrystal layers.

### BACKGROUND

At the present time, critical dimensions in semiconductor process are most commonly measured by the secondary electron microscopy, i.e. CD SEM. However, the measurement requires collection of several tens of thousands of data points, taking the CD SEM at least 150 hours or even longer. The novel advanced electron beam linewidth defect scanning machine (Scanning Electron Microscope eP5 by ASML) is capable of quickly and accurately measure several tens of thousands of data points.

A silicon polycrystal layer is one of the most important layers in integrated circuit manufacturing. However, when using ASML's eP5 to measure the pre-etching wafer circuit patterns at technology nodes 28 nm and beyond, there is a problem that the user designed data set is not easily aligned with the wafer circuit patterns, this results in measurement errors. Often engineers need to spend nearly a week checking and screening tens of thousands of measurement data, which is inefficient.

### BRIEF SUMMARY

The application provides a method for reducing large measurement errors and improving accuracy of critical pattern dimensions of polycrystal layers in semiconductor process technology.
The method for reducing measurement errors includes the following steps: step 1: providing wafer circuit patterns to be measured;
step 2: defining rules to classify the wafer circuit patterns to be measured into a first type of wafer circuit patterns and a second type of wafer circuit patterns, wherein the first type of wafer circuit patterns are easily measurable with an electron beam linewidth defect scanning machine, and the second type of wafer circuit patterns are not easily measurable with the electron beam linewidth defect scanning machine;
step 3: for the first type of wafer circuit patterns, performing automatic measurements with the electron beam linewidth defect scanning machine; for the second type of wafer circuit patterns, firstly aligning manually user designed wafer circuit patterns with the second type of wafer circuit patterns, and performing measurement on the second type of wafer circuit patterns with the electron beam linewidth defect scanning machine to obtain a first group of measurement result; and repeating the measurement to obtain a second group of measurement results;
step 4: checking the first and second groups of measurement results to determine whether there is a measurement error in one of the wafer circuit patterns; in a case that there is a measurement error in a pattern, performing step 3 on the wafer circuit pattern with the measurement error again; and in a case that there is no measurement error in the wafer circuit patterns, performing step 5; and step 5: analyzing the measurement results.

According to some embodiments, in step 2, the wafer circuit patterns easily measurable by the electron beam linewidth defect scanning machine are easily aligned with user designed patterns.

According to some embodiments, in step 2, the wafer circuit patterns not easily measurable by the electron beam linewidth defect scanning machine are not easily aligned with the user designed patterns.

According to some embodiments, in step 2, defining rules to classify the wafer circuit patterns includes calculating the number of line-end corners in the pattern and the linewidth standard deviation Std_{Width} of the wafer circuit pattern in a square area which has its side equal to the scanning range of the electron beam linewidth defect scanning machine.

According to some embodiments, in step 1, the wafer circuit patterns to be measured are wafer circuit patterns of polysilicon layers.

According to some embodiments, in step 2, the first type of wafer circuit patterns includes three scenarios; a first scenario of wafer circuit patterns is that their number of line-end corners in the square area which has a side equal to the scanning range of the electron beam linewidth defect scanning machine is greater than 0; a second scenario of wafer circuit patterns is that the number of line-end corners in the same area is 0 and the linewidth standard deviation Std_{Width} equals to 0; and a third scenario of wafer circuit patterns is that the number of line-end corners in the same area is 0 and the linewidth standard deviation Std_{Width} equals to or greater than 0.006.

According to some embodiments, in step 2, the second type of wafer circuit patterns have the number of line-end corners in the square area which has the side equal to the scanning range of the electron beam linewidth defect scanning machine is 0 and the linewidth standard deviation Std_{Width} is in a range between 0 and 0.006.

According to some embodiments, in step 5, analyzing the measurement results without measurement errors includes first analyzing the measurement results containing measurement errors of the wafer circuit patterns and performing measurement again to improve the accuracy of the final measurement results.

As described above, the method for reducing measurement errors of critical pattern dimensions in polycrystal layers disclosed in this application has the following beneficial effects: the method reduces the measurement error rate from 5% to 0.1%, and improves accuracy and efficiency in acquiring good measurement results.

### BRIEF DESCRIPTION OF THE DRAWINGS

FIG. 1 illustrates a schematic diagram of a wafer circuit pattern that the number of line-end corners is more than 0 in the square area which has the side equal to the scanning range of the electron beam linewidth defect scanning machine according to an embodiment.

FIG. 2 illustrates a schematic diagram of wafer circuit patterns that the number of line-end corners in the square area which has the side equal to the scanning range of the electron beam linewidth defect scanning machine is 0 according to one embodiment.

FIG. 3 illustrates a schematic diagram of wafer circuit patterns that the number of line-end corners in the square area which has the side equal to the scanning range of the electron beam linewidth defect scanning machine is more than 0 (2 line end corners) according to one embodiment.

FIG. 4 illustrates a schematic diagram of wafer circuit patterns that the number of line-end corners in the square area which has the side equal to the scanning range of the electron beam linewidth defect scanning machine is 0 and a linewidth standard deviation is 0 according to one embodiment.

FIG. 5 illustrates a schematic diagram of wafer circuit patterns that the number of line-end corners in the square area which has the side equal to the scanning range of the electron beam linewidth defect scanning machine is 0 and a linewidth standard deviation is greater than 0.006 according to this application.

FIG. 6 illustrates a schematic diagram of wafer circuit patterns that the number of line-end corners in the square area which has the side equal to the scanning range of the electron beam linewidth defect scanning machine is 0 and a linewidth standard deviation is between 0 and 0.006 according to the embodiment.

FIG. 7 illustrates a schematic diagram of wafer circuit patterns that the number of line-end corners in the square area which has the side equal to the scanning range of the electron beam linewidth defect scanning machine is 0 and a linewidth standard deviation is 0.003 according to the embodiment.

FIG. 8 illustrates a schematic diagram of wafer circuit patterns that the number of line-end corners in the square area which has the side equal to the scanning range of the electron beam linewidth defect scanning machine is 0 and a linewidth standard deviation is 0.005 according to the embodiment.

FIG. 9 illustrates a flowchart of a method for reducing measurement errors of critical pattern dimensions of polycrystal layers according to the embodiment.

### DETAILED DESCRIPTION OF THE EMBODIMENTS

The embodiments of this application will be described below through specific examples. Those skilled in the art can easily understand the other advantages and effects of this application from the content disclosed in this description. This application may also be implemented or applied through other different specific implementation modes, and the details in this description may be modified or changed based on different perspectives and applications without deviating from the spirit of this application.

Please refer to FIG. 1 to FIG. 9. It is to be understood that the drawings provided in the embodiments are only used for schematically describing the basic concept of this application. Therefore, the drawings only show the components related to this application and are not drawn according to the actual number, shape, and size of the components during implementation. The type, number and scale of each component during actual implementation may be freely changed, and the layout of the component may also be more complex.

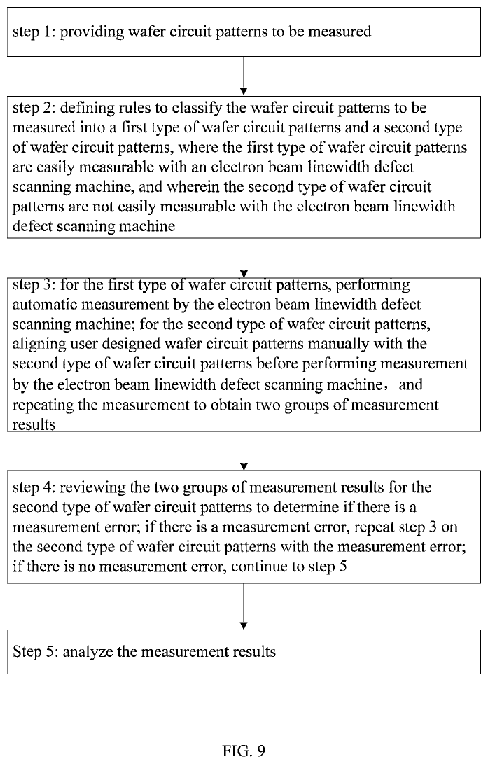

This application provides a method for reducing measurement errors of critical pattern dimensions of polycrystal layers. Referring to FIG. 9 which illustrates a flowchart of a method for reducing measurement errors of critical pattern dimensions of polycrystal layers according to this application, the method at least includes the following steps:

In step 1, wafer circuit patterns to be measured are provided. The wafer circuit patterns to be measured are wafer circuit patterns.

Further, in this embodiment of this application, in step 1, the wafer circuit patterns to be measured are wafer circuit patterns of polysilicon layers.

In step 2, rules are written to classify the wafer circuit patterns to be measured into a first type of wafer circuit patterns and a second type of wafer circuit patterns. The first type of wafer circuit patterns are wafer circuit patterns easily measurable for an electron beam linewidth defect scanning machine. The second type of wafer circuit patterns are wafer circuit patterns not easily measurable for the electron beam linewidth defect scanning machine.

Further, in this embodiment of this application, the wafer circuit patterns easily measurable for the electron beam linewidth defect scanning machine are wafer circuit patterns that the user designed wafer circuit patterns are easily aligned with the wafer circuit patterns.

Further, in this embodiment of this application, in step 2, the wafer circuit patterns not easily measurable for the electron beam linewidth defect scanning machine are wafer circuit patterns that the user designer wafer circuit patterns are not easily aligned with the wafer circuit patterns.

Further, in this embodiment of this application, in step 2, defining rules includes calculating the number of line-end corners and a linewidth standard deviation Std_{Width} of wafer circuit patterns in the square area which has the side equal to the scanning range of the electron beam linewidth defect scanning machine.

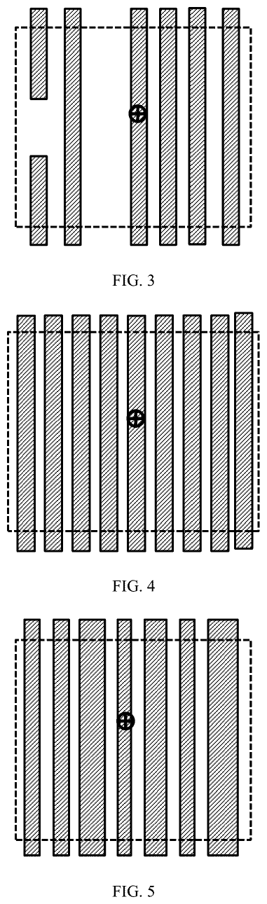

Further, in this embodiment of this application, in step 2, the first type of wafer circuit patterns includes three scenarios; a first scenario of wafer circuit patterns is that the number of line-end corners is more than 0 in the square area which has the side equal to the scanning range of the electron beam linewidth defect scanning machine. Referring to FIG. 1, a first scenario of wafer circuit patterns is that the number of line-end corners is more than 0 in the square area, indicated by a dashed square box in FIG. 1, which has the side Rx2 equal to the scanning range of the electron beam linewidth defect scanning machine. What are enclosed in circles in FIG. 1 are corners in the wafer circuit pattern. The number of line-end corners in FIG. 3 is more than 0. Referring to FIG. 3, the number of line-end corners in the designated square in FIG. 3 is also more than 0.

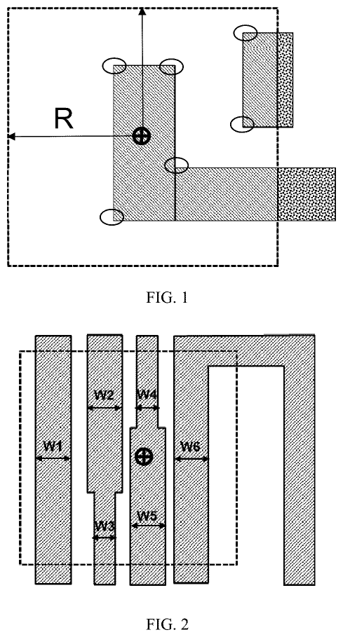

A second scenario of wafer circuit patterns is that the number of line-end corners in the square area which has the side equal to the scanning range of the electron beam linewidth defect scanning machine is 0 and the linewidth standard deviation Std_{Width} equals to 0. Refer to FIG. 2. In FIG. 2, the number of line-end corners of the wafer circuit pattern is 0 in the square area, indicated by a dashed square box in FIG. 2, which has the side equal to the scanning range of the electron beam linewidth defect scanning machine that is, the number of line-end corners is 0, and the linewidth standard deviation Std_{Width} equals to 0. The linewidth standard deviation

$${Std}_{Width} = \sqrt{\frac{1}{n - 1} {\sum }_{i = 1}^{n} {( {X}_{i} - ( \frac{1}{n} {\sum }_{i = 1}^{n} {X}_{i} ) )}^{2}} ,$$

where Xi is the linewidth of an ith pattern in the range indicated by the dashed square box. In FIG. 2, from left to right, the first to the sixth linewidths are sequentially labeled as W1, W2, W3, W4, W5 and W6. In the standard deviation formula above, n is the number of patterns for calculating linewidths in the scanning range. Referring to FIG. 4, the number of line-end corners in FIG. 4 is 0 and the linewidth standard deviation Std_{Width} is equal to 0.

A third scenario of wafer circuit patterns is that the number of line-end corners in the square area which has the side equal to the scanning range of the electron beam linewidth defect scanning machine is 0 and the linewidth standard deviation Std_{Width} is equal to or greater than 0.006. Refer to FIG. 5. In FIG. 5, the number of line-end corners is 0 and the linewidth standard deviation Std_{Width} is equal to or greater than 0.006.

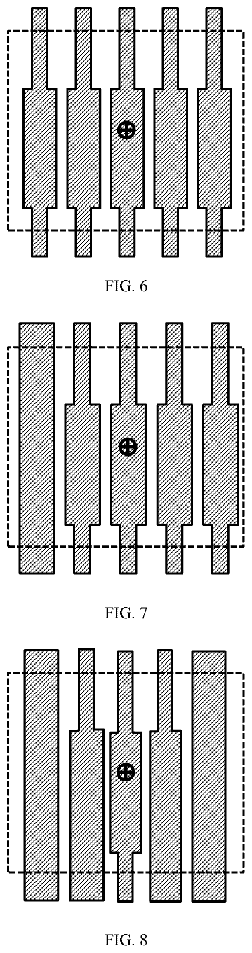

Further, in this embodiment of this application, in step 2, the second type of wafer circuit patterns include wafer circuit patterns that the number of line-end corners in the square area which has the side equal to the scanning range of the electron beam linewidth defect scanning machine is 0 and the linewidth standard deviation Std_{Width} is between 0 and 0.006. Refer to FIG. 6. The wafer circuit patterns in FIG. 6 represent the second type of wafer circuit patterns, the number of line-end corners of the wafer circuit patterns is 0, and the linewidth standard deviation Std_{Width} is equal to 0.001. The wafer circuit patterns in FIG. 7 represent the second type of wafer circuit patterns, the number of line-end corners of the wafer circuit patterns is 0, and the linewidth standard deviation Std_{Width} is equal to 0.003. The wafer circuit patterns in FIG. 8 represent the second type of wafer circuit patterns, the number of line-end corners of the wafer circuit patterns is 0, and the linewidth standard deviation Std_{Width} is equal to 0.005.

In step 3, for the first type of wafer circuit patterns, automatic measurement is performed by using the electron beam linewidth defect scanning machine; for the second type of wafer circuit patterns, firstly user design wafer circuit patterns are aligned manually with the second type of wafer circuit patterns, and then measurement is performed on the second type of wafer circuit patterns by using the electron beam linewidth defect scanning machine to obtain the first group of measurement result; and repeating the measurement to obtain two groups of measurement results.

In step 4, the two groups of measurement results are checked to determine whether there is a pattern with a measurement error; in a case that there is a pattern with a measurement error, step 3 is performed on the pattern with the measurement error again; in a case that there is no pattern with a measurement error, step 5 is performed.

In step 5, the measurement results are analyzed.

Further, in this embodiment of this application, in step 5, analyzing the measurement results without measurement errors includes analyzing the wafer circuit patterns with measurement errors in the measurement results and performing measurement again to improve the accuracy of final measurement results.

To sum up, the method reduces the measurement error rate from 5% to 0.1%, and improves the accuracy and the efficiency of acquiring good measurement results. This technique can overcome various drawbacks in the existing technology, so presents a great industrial utilization value.

The above embodiments are only intended to exemplarily describe the principle and efficacy of this application, instead of limiting this application. Anyone skilled in the art may modify or change the above embodiments without departing from the spirit and scope of this application. Therefore, all equivalent modifications or changes made by those with ordinary knowledge in the technical field without departing from the spirit and technical concept disclosed in this application should still be covered by the claims of this application.

What is claimed is:

1. A method for reducing measurement errors of critical pattern dimensions of polycrystal layers, at least comprising:
step 1: providing wafer circuit patterns to be measured;
step 2: defining rules to classify the wafer circuit patterns to be measured into a first type of wafer circuit patterns and a second type of wafer circuit patterns, where the first type of wafer circuit patterns are easily measurable with an electron beam linewidth defect scanning machine, and wherein the second type of wafer circuit patterns are not easily measurable with the electron beam linewidth defect scanning machine;
step 3: for the first type of wafer circuit patterns, performing automatic measurement by the electron beam linewidth defect scanning machine; for the second type of wafer circuit patterns, aligning user designed wafer circuit patterns manually with the second type of wafer circuit patterns before performing measurement by the electron beam linewidth defect scanning machine, and repeating the measurement to obtain two groups of measurement results;
step 4: reviewing the two groups of measurement results for the second type of wafer circuit patterns to determine if there is a measurement error; if there is a measurement error, repeat step 3 on the second type of wafer circuit patterns with the measurement error; if there is no measurement error, continue to step 5; and
step 5: analyzing the measurement results.

2. The method for reducing measurement errors of critical pattern dimensions of polycrystal layers according to claim 1, wherein in step 2, the wafer circuit patterns easily measurable with the electron beam linewidth defect scanning machine are easily alignable to the user designed wafer circuit patterns.

3. The method for reducing measurement errors of critical pattern dimensions of polycrystal layers according to claim 1, wherein in step 2, the wafer circuit patterns not easily measurable for the electron beam linewidth defect scanning machine are not easily alignable to the user designed wafer circuit patterns.

4. The method for reducing measurement errors of critical pattern dimensions of polycrystal layers according to claim 1, wherein the defining the rules in step 2 further comprises calculating a number of line-end corners and a linewidth standard deviation Std_{Width} of the wafer circuit patterns in a square area which has a side length equal to a scanning range of the electron beam linewidth defect scanning machine.

5. The method for reducing measurement errors of critical pattern dimensions of polycrystal layers according to claim 4, wherein in step 1, the wafer circuit patterns to be measured are in the polysilicon layers.

6. The method for reducing measurement errors of critical pattern dimensions of polycrystal layers according to claim 5, wherein in step 2, the first type of wafer circuit patterns comprises three scenarios; in a first scenario, the number of line-end corners is more than 0 in said square area; in a second scenario, the number of line-end corners in said square area is 0 and the linewidth standard deviation Std_{Width} equals to 0; in a third scenario, the number of line-end corners in said square area is 0 and the linewidth standard deviation Std_{Width} is equal to or greater than 0.006.

7. The method for reducing measurement errors of critical pattern dimensions of polycrystal layers according to claim 5, wherein in step 2, in the second type of wafer circuit patterns, the number of line-end corners in said square area is 0 and the linewidth standard deviation Std_{Width} is between 0 and 0.006.

8. The method for reducing measurement errors of critical pattern dimensions of polycrystal layers according to claim 1, wherein step 5 further comprises performing step 3 and step 4 again if there is an error in the measurement results.
